(19) United States
(12) Patent Application Publication
(10) Pub. No.: US 2006/0087822 A1
(43) Pub. Date: Apr. 27, 2006

(54) Integrated structure with CPU and north bridge chip

(75) Inventor: Wei-Jen Cheng, Shindian City (TW)

Correspondence Address: BACON & THOMAS, PLLC, 625 SLATERS LANE, FOURTH FLOOR, ALEXANDRIA, VA, 22314, US

(73) Assignee: VIA Technologies, Inc., Shindian City (TW)

(21) Appl. No.: 11/031,005

(22) Filed: Jan. 10, 2005

(30) Foreign Application Priority Data
Oct. 21, 2004 (TW) 093132061

(51) Int. Cl. H05K 1/14

(52) U.S. Cl. 361/784

(57) ABSTRACT

An integrated structure comprises a north bridge substrate, a CPU, and a north bridge chip. The north bridge substrate has a first surface and a second surface opposite to the first surface. A first area and a plurality of first pads are disposed on the first surface. A second area and a plurality of second pads are disposed on the second surface. The first pads are electrically connected with the second pads by a plurality of conducting traces. The CPU is disposed on the first area of the first surface and is electrically connected with the first pads. The CPU is electrically connected with the second pads via the first pads. North bridge chip is disposed on the second area of the second surface and is electrically connected with the second solder pads.

### BACKGROUND OF THE INVENTION

1. Field of Invention

The invention relates to an integrated structure and, in particular, to an integrated structure with a CPU and a north bridge chip.

2. Related Art

The manufacturing technology for electrical device has been well developed, so that the main board usually has powerful functions and broadened application scopes. For example, the home PC, industrial computer, car computer, game station and the likes all need the main board.

The layout density of the main board is depended on the required functions and the product size. In present, the product has a trend toward minimization and multiple functions, so that the main board must have decreased dimension and more functions. Thus, the layout density of the main board must grow higher, resulting in the difficult in main board design.

Take the home PC as an example, as shown in FIG. 1, several memory sockets 11, several I/O card sockets 12, a south bridge module 13, an I/O connection terminal 14, a front side bus (FSB) 15, a graphic card socket 16, a central processing unit (CPU) 20 and a north bridge module 30 are disposed on a circuit board 10, and the above components compose a main board 1.

Of course, to achieve different functions, some components may be added or removed. When the function becomes more and more powerful, the required components and layout density correspondingly tend to more complex. This will cause the design problem for minimization products. Therefore, it is an important subjective of the invention to efficiently utilize the available area of the main board for simplifying the layout design.

### SUMMARY OF THE INVENTION

In view of the foregoing, the invention is to provide an integrated structure with a CPU and a north bridge chip, which occupies less layout area on a main board.

To achieve the above, an integrated structure of the invention includes a north bridge substrate, a central processing unit (CPU) and a north bridge chip. The north bridge substrate has a first surface and a second surface opposite to the first surface. A first area and a plurality of first pads are disposed on the first surface, and a second area and a plurality of second pads are disposed on the second surface. The first pads are electrically connected with the second pads by a plurality of conducting traces. The CPU is disposed on the first area of the first surface and is electrically connected with the first pads. Herein, the CPU is electrically connected with the second pads via the first pads. The north bridge chip is disposed on the second area of the second surface and is electrically connected with the second solder pads.

As mentioned above, the integrated structure with a CPU and a north bridge chip of the invention integrates the conventional separated CPU and north bridge chip into a whole. Therefore, the occupied layout area of the main board can be reduced. When the main board is minimized for matching the trend of minimization products, the design for the main board becomes easier.

### BRIEF DESCRIPTION OF THE DRAWINGS

The invention will become more fully understood from the detailed description given herein below illustration only, and thus is not limitative of the present invention, and wherein:

FIG. 1 is a schematic view showing the conventional main board;

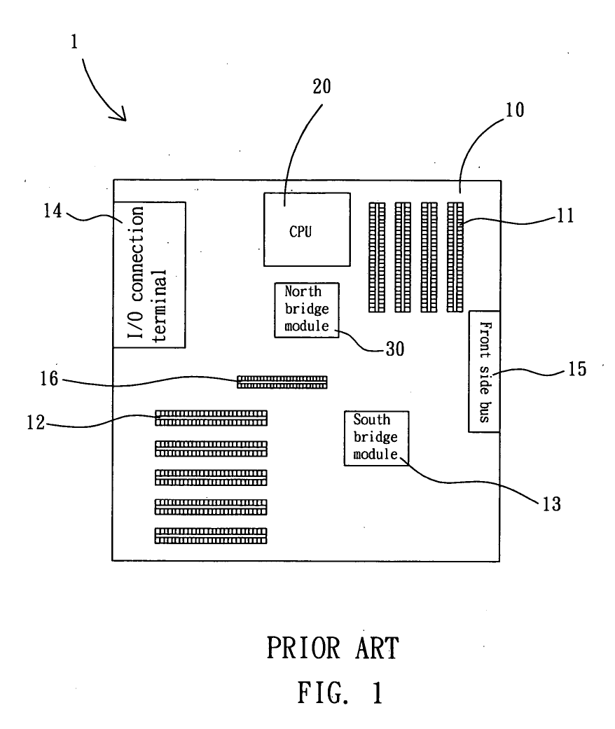

FIG. 2 is a sectional view showing an integrated structure with a CPU and a north bridge chip according to a preferred embodiment of the invention;

FIGS. 3A to 3B are top and bottom views showing a north bridge substrate of the integrated structure with a CPU and a north bridge chip according to the embodiment of the invention; and

FIG. 4 is a sectional view showing another integrated structure with a CPU and a north bridge chip according to the embodiment of the invention.

### DETAILED DESCRIPTION OF THE INVENTION

The present invention will be apparent from the following detailed description, which proceeds with reference to the accompanying drawings, wherein the same references relate to the same elements.

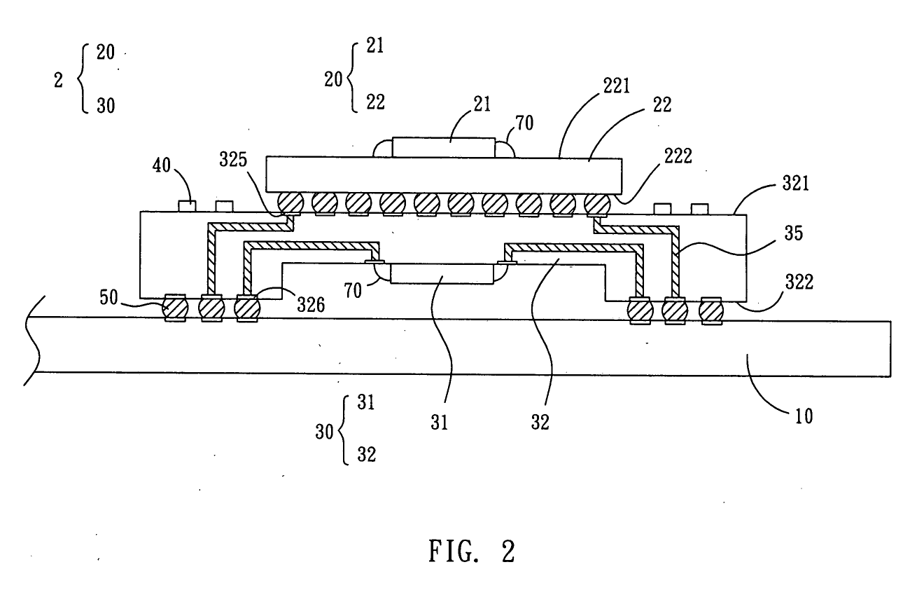

With reference to FIG. 2, an integrated structure 2 according to a preferred embodiment of the invention includes a central processing unit (CPU) 20 and a north bridge module 30. The CPU 20 includes a CPU chip 21 and a CPU substrate 22. The north bridge module 30 includes a north bridge chip 31 and a north bridge substrate 32.

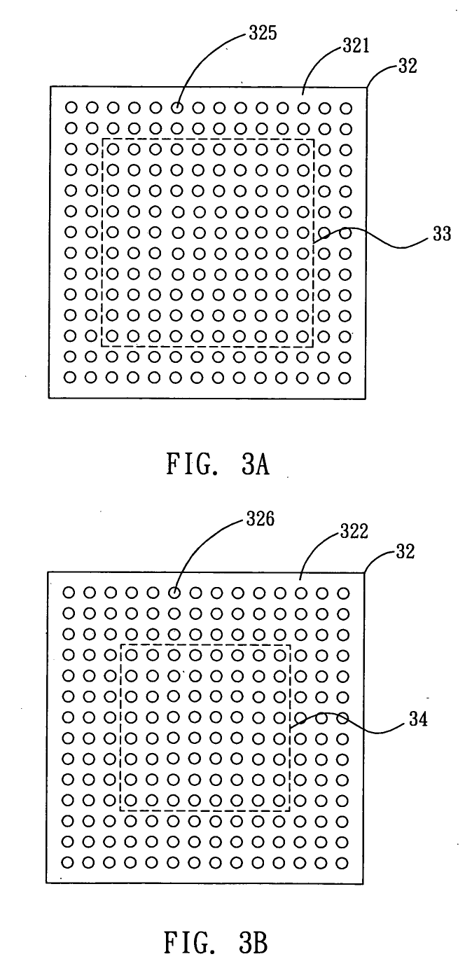

The north bridge substrate 32 has a first surface 321 and a second surface 322 opposite to the first surface 321. A first area 33 and a plurality of first pads 325 are disposed on the first surface 321 (as shown in FIG. 3A), and a second area 34 and a plurality of second pads 326 are disposed on the second surface 322 (as shown in FIG. 3B). The first pads 325 are electrically connected with the second pads 326 via a plurality of conducting traces 35. In addition, a plurality of conducting bumps 50 are disposed on the second pads 326 for electrically connecting with a circuit board 10. In the present embodiment, several capacitors 40 are disposed and are electrically connected with some first pads 325 located in other than the first area 33. The north bridge substrate 32, of the embodiment is a cavity-down substrate, and the second area 34 is located in the cavity of the cavity-down substrate. Otherwise, the north bridge substrate of the invention can be a multi-layer north bridge substrate.

As shown in FIG. 2, the CPU substrate 22 includes a third surface 221 and a fourth surface 222. The CPU chip 21 is disposed on the third surface 221 of the CPU substrate 22. The fourth surface 222 of the CPU substrate 22 is electrically connected with some first pads 325 and disposed facing to the first area 33 on the first surface 321 of the north bridge substrate 32. Thus, the CPU 20 is connected with the second pads 326 via the first pads 325. In the invention, the CPU chip 21 can be disposed on the third surface 221 of the CPU substrate 22 by the flip-chip technology or wire-bonding technology. In the embodiment, the CPU chip 21 is disposed on the third surface 221 by the wire-bonding technology, and the wires 70 are used to connect the CPU chip 21 to the CPU substrate 22.

The north bridge chip 31 is disposed on the second area 34 on the second surface 322 of the north bridge substrate 32 and is electrically connected with some second pads 326. In the invention, the north bridge chip 31 can be disposed on the second area 34 by the flip-chip technology or wire-bonding technology. In the embodiment, the north bridge chip 31 is disposed on the second area 34 by the wire-bonding technology, and the wires 70 are used to connect the north bridge chip 31 to the second pads 326.

In the current embodiment, the CPU 20 is electrically connected with the north bridge chip 31 via the first pads 325 and the second pads 326, and is electrically connected with the circuit board 10 via the first pads 325, the second pads 326 and the conducting bumps 50. In addition, the north bridge chip 31 is electrically connected with the circuit board 10 via the second pads 326 and the conducting bumps 50.

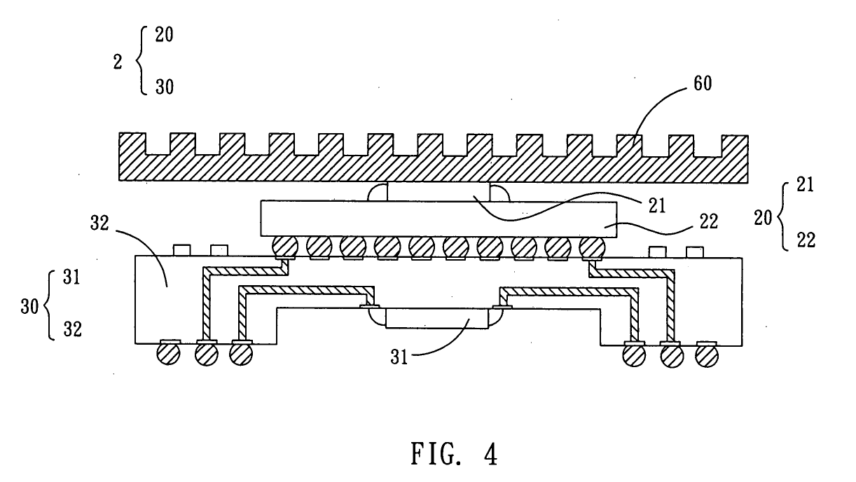

With reference to FIG. 4, the integrated structure 2 may further includes a heat-dissipation module 60, which is disposed on the CPU 20. The heat-dissipation module 60 may include a fan and/or a heat sink for dissipating the heat generated by the integrated structure 2. Accordingly, the CPU 20 and the north bridge module 30 can function normally.

In summary, the integrated structure with a CPU and a north bridge chip of the invention integrates the CPU and north bridge chip on the north bridge substrate. Then, the integrated structure of the invention can be disposed on the circuit board. Comparing with the prior art that utilizes separated CPU and north bridge chip installed on the circuit board, the invention can efficiently utilize the layout area of the main board. Accordingly, the occupied layout area on the circuit board can be reduced, which makes the design for the main board easier.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An integrated structure, comprising:
a north bridge substrate, which has a first surface and a second surface opposite to the first surface, wherein a first area and a plurality of first pads are disposed on the first surface, a second area and a plurality of second pads are disposed on the second surface, and the first pads are electrically connected with the second pads by a plurality of conducting traces;
a central processing unit (CPU), which is disposed on the first area of the first surface, is electrically connected with the first pads, and is electrically connected with the second pads via the first pads; and
a north bridge chip, which is disposed on the second area of the second surface and is electrically connected with the second solder pads.

2. The integrated structure of claim 1, wherein the north bridge substrate is a cavity-down substrate, and the second area is located in a cavity of the cavity-down substrate.

3. The integrated structure of claim 1, wherein the north bridge substrate is a multi-layer north bridge substrate.

4. The integrated structure of claim 1, wherein the CPU is disposed on the first area by a flip-chip technology.

5. The integrated structure of claim 1, wherein the CPU is disposed on the first area by a wire-bonding technology.

6. The integrated structure of claim 1, wherein the north bridge chip is disposed on the second area by a flip-chip technology.

7. The integrated structure of claim 1, wherein the north bridge chip is disposed on the second area by a wire-bonding technology.

8. The integrated structure of claim 1, wherein the CPU is electrically connected with the north bridge chip via the first pads and the second pads.

9. The integrated structure of claim 1, further comprising:
a plurality of conducting bumps, which are disposed on the second pads and are for electrically connected with a circuit board.

10. The integrated structure of claim 9, wherein the CPU is electrically connected with the circuit board via the first pads, the second pads and the bumps.

11. The integrated structure of claim 9, wherein the north bridge chip is electrically connected with the circuit board via the second pads and the bumps.

12. The integrated structure of claim 1, further comprising:
a heat-dissipation module, which is disposed on the CPU.

13. The integrated structure of claim 12, wherein the heat-dissipation module includes a fan.

14. The integrated structure of claim 12, wherein the heat-dissipation module includes a heat sink.
